(19) United States
(12) Patent Application Publication
(10) Pub. No.: US 2020/0349984 A1
(43) Pub. Date: Nov. 5, 2020

(54) SEMICONDUCTOR PACKAGE CONFIGURATION FOR REDUCED VIA AND ROUTING LAYER REQUIREMENTS

(71) Applicant: Western Digital Technologies, Inc., San Jose, CA (US)

(72) Inventors: Tenzin Namgyal Maja, Bangalore (IN); Rohith V Kamath, Bangalore (IN)

(21) Appl. No.: 16/400,708

(22) Filed: May 1, 2019

(51) Int. Cl. G11C 5/06; H05K 1/18; H05K 1/11; H01L 27/11519; H01L 27/11524; H01L 27/11565; H01L 27/1157

(52) U.S. Cl. CPC G11C 5/06; H05K 1/181; H05K 1/116; H05K 2201/10159; H01L 27/11524; H01L 27/11565; H01L 27/1157; H01L 27/11519

(57) ABSTRACT

Semiconductor packages are mounted opposite one another across a printed circuit board, where one of the packages is configured with a mirrored pin assignment of the other.

### BACKGROUND

Conventional solid state drives utilize standard 170-pin memory packages and pin-outs defined in the Joint Electron Device Engineering Council (JEDEC) specification. This causes complexities when the printed circuit board (PCB) used between packages has double sided placement. Additional vias and signal layers in the PCB are typically required. This raises costs due to higher layer count in the PCB. In addition, the signal traces add to stub length because the available channels are not operated at the same time.

FIG. 1 illustrates an example of a conventional memory device 100 utilizing NAND memory packages on a double-sided PCB. FIG. 2 depicts corresponding routing and vias for some exemplary pins of the conventional configuration routing 200, FIG. 3 depicts the conventional configuration pinout 300 of the NAND memory packages, and FIG. 4 depicts the conventional pin assignments 400 for the NAND memory packages.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a cross sectional view of a conventional memory device 100.

FIG. 2 illustrates a top view of conventional memory device 100.

FIG. 3 illustrates a top view of a conventional configuration pinout 300.

FIG. 4 illustrates a top view of conventional pin assignments 400.

FIG. 5 illustrates a cross sectional view of memory device 500 in accordance with one embodiment.

FIG. 6 illustrates an example of mirrored configuration routing 600 in accordance with one embodiment.

FIG. 7 illustrates a top view of mirrored configuration pinout 700 in accordance with one embodiment.

FIG. 8 illustrates a top view of mirrored pin assignments 800 in accordance with one embodiment.

FIG. 9 illustrates a top view of one example conventional configuration routing 900.

FIG. 10 illustrates an example of mirrored configuration routing 1000 in accordance with one embodiment.

FIG. 11 illustrates NAND memory package pair configuration 1100 in accordance with one embodiment.

### DETAILED DESCRIPTION

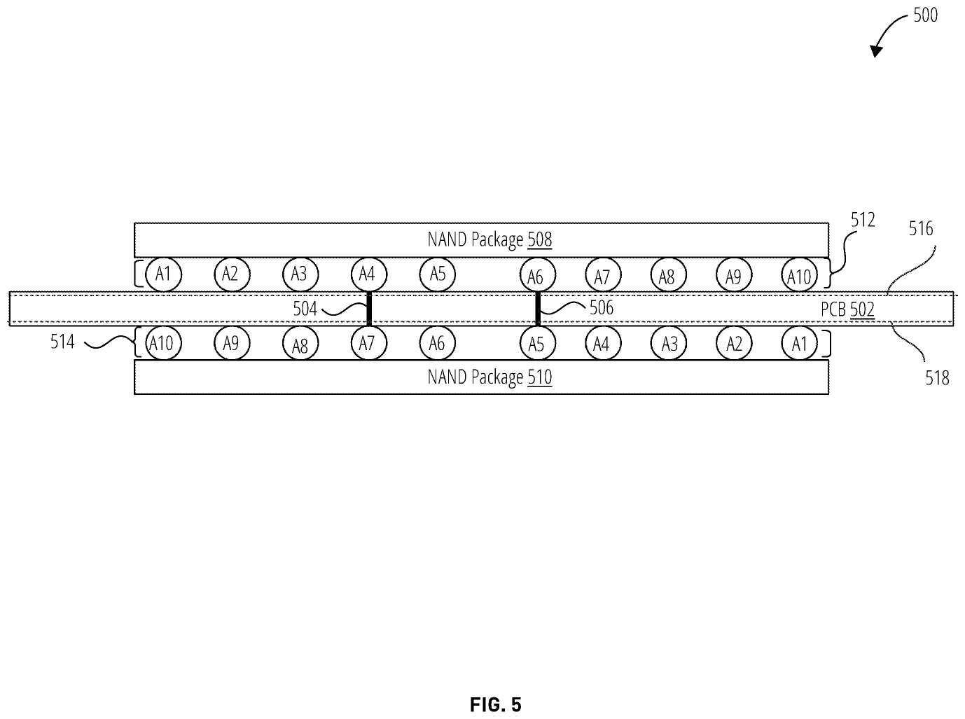

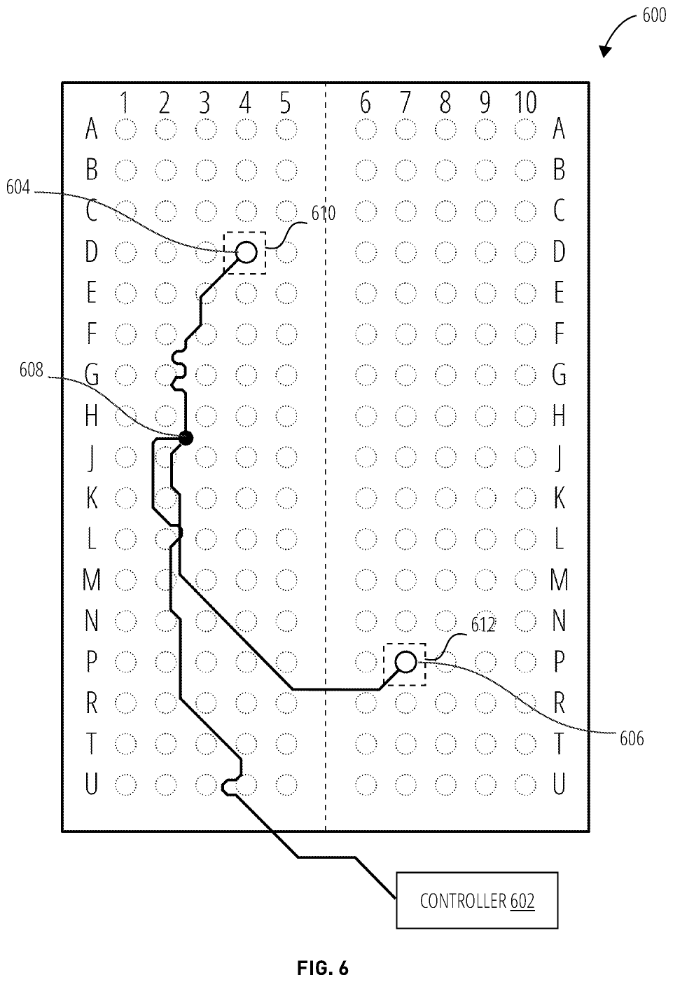

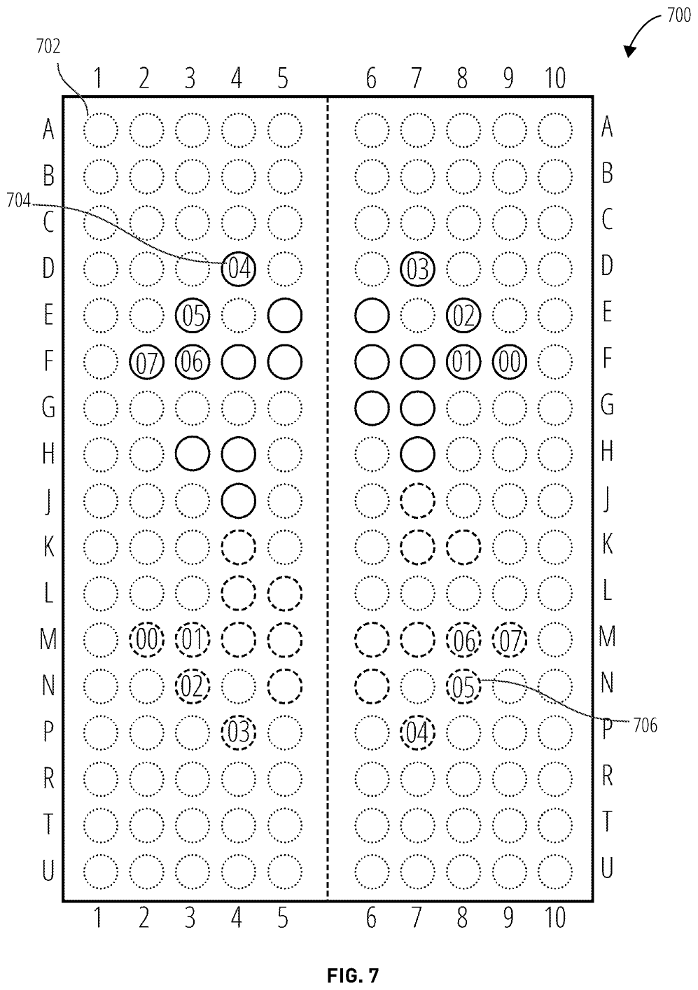

Two NAND packages are placed on the opposite sides of the PCB with the pin-out aligned as depicted in FIG. 5. The solution utilizes a mirrored ball-out NAND package such that signals from the PCB may be directly connected in the Z plane using standard via's. The stub length is limited to the via length, as depicted for D4 in FIG. 6, substantially improving the speed of the interface. A resulting pin assignment on the interface is depicted in FIG. 7.

The new approach utilizes only two layers of the PCB to route signals whereas the conventional approach requires five layers. The number of vias utilized is reduced to three from seven. Due to the shorter signal paths the signal eye may be widened both horizontally and vertically, improving the performance of the package interfaces.

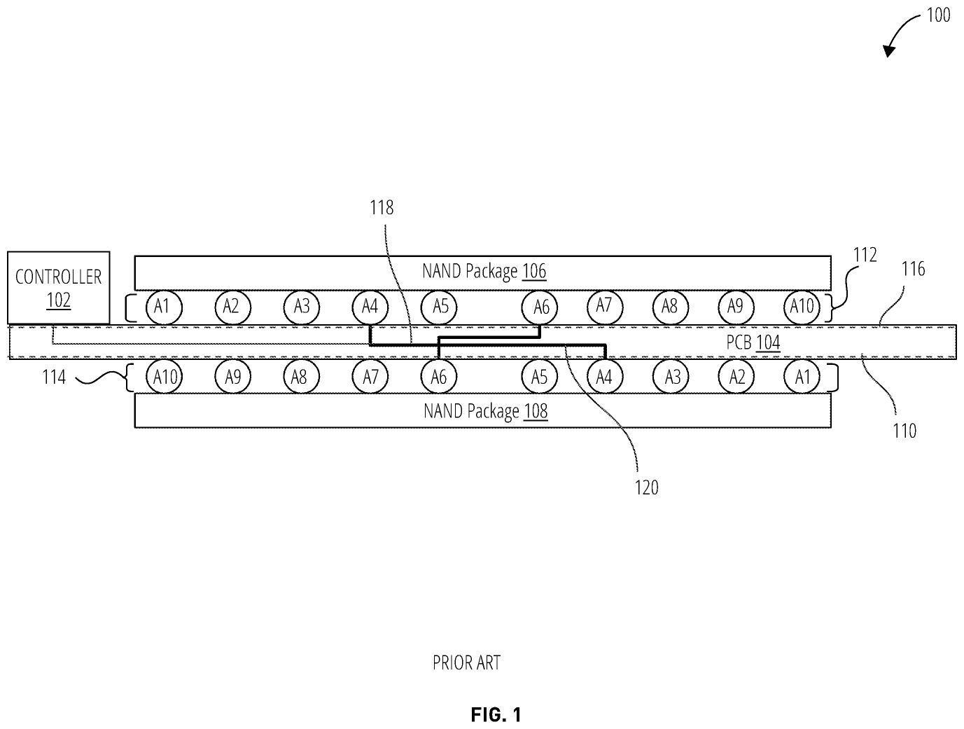

FIG. 1 illustrates a cross sectional view of a conventional memory device 100 showing a printed circuit board (PCB 104) between a first semiconductor package 106 and a second semiconductor package 108. The first semiconductor package 106 and the second semiconductor package 108 have the same pin assignments (the same functional behavior assigned to pins in the same position), but are placed in opposing directions with respect to one another across the PCB 104. The first semiconductor package 106 comprises a plurality of pins 112 (arranged left to right A1, A2, A3, A4, A5, A6, A7, A8, A9, and A10) mounted to a first side 116 of the PCB 104. The second semiconductor package 108 comprises a plurality of pins 114 (arranged left to right A10, A9, A8, A7, A6, A5, A4, A3, A2, and A1) mounted to the second side 110 of the PCB 104. (Only one row of pins is shown; each package will typically have many such rows.)

The first semiconductor package 106 and the second semiconductor package 108 may be NAND packages with a JEDEC 170-pin ball grid array (BGA) pinout that includes channel 0 pins, channel 1 pins, and inactive pins. For example, in the conventional memory device 100, corresponding pins on opposite NAND packages such as A4 on first semiconductor package 106 and A4 on second semiconductor package 108 and A6 on first semiconductor package 106 and A6 on second semiconductor package 108 are coupled by connection 118 and connection 120, respectively, from controller 102. These connections traverse through multiple routing layers (typically, five layers) through the PCB 104 to form two memory channels from the two packages.

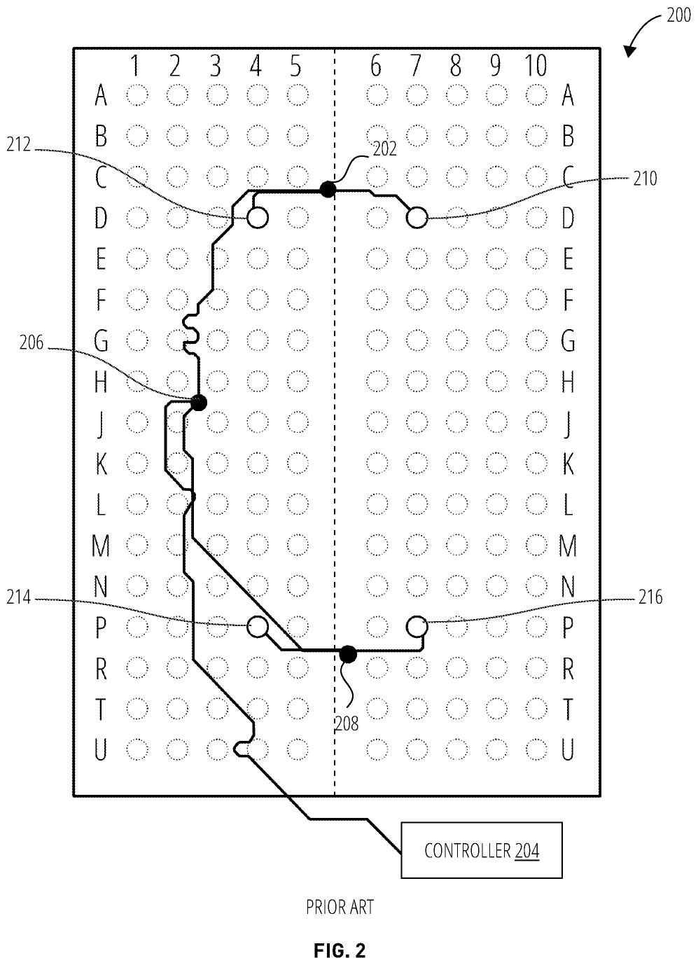

FIG. 2 illustrates a top view of the conventional configuration routing 200 showing the overlay of two NAND packages with pins mounted to the PCB in accordance with the JEDEC 170-pin BGA pinout resulting in a non-mirrored alignment. In the conventional configuration routing 200, a routing from the controller 204 to D4 on a first NAND package (first side pin 212 of a first memory channel) requires via 202 ND via 206. Likewise a routing from the controller 204 to D4 on the second NAND package (second side pin 210 of a second memory channel) requires via 202 and via 206. Furthermore the routing traverses through more than two routing layers of the PCB 104. Similarly, the routing from the controller 204 to P7 on the first NAND package (first side pin 216 of the first memory channel) requires via 206 and via 208, as does the routing from the controller 204 to P7 on the second NAND package (second side pin 214 of the second memory channel), again traversing through more than two routing layers.

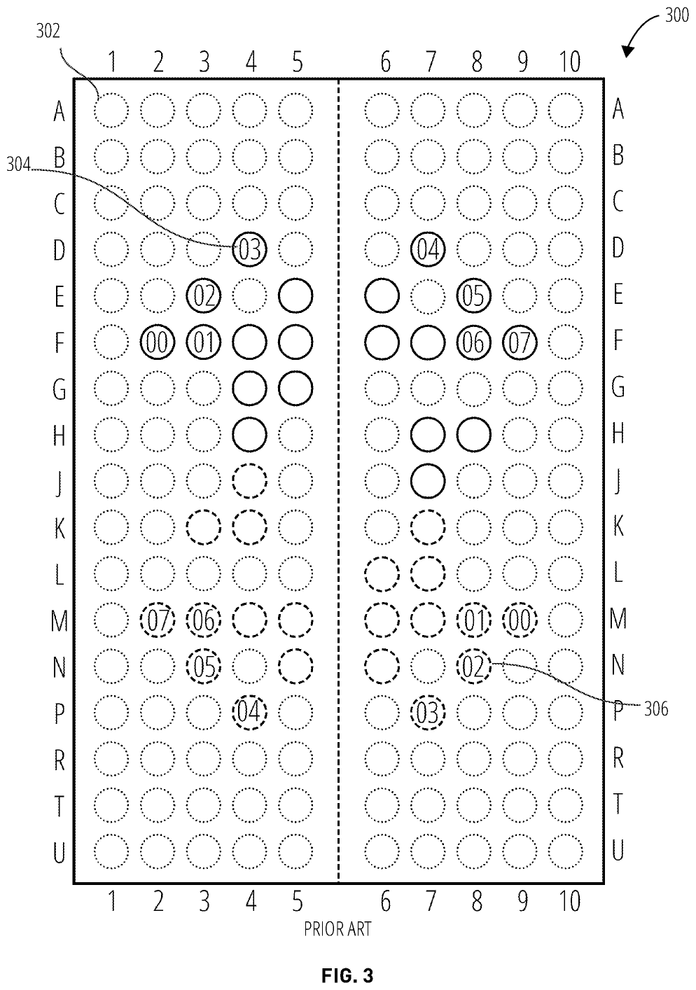

FIG. 3 illustrates a top view of a conventional configuration pinout 300 of a NAND memory package that may be utilized as either the first NAND package or the second NAND package as part of a NAND flash array. The conventional configuration pinout 300 comprises inactive pins 302 (dotted outline), channel 1 pins 304 (solid outline), and channel 0 pins 306 (dashed outline). In the conventional configuration pinout 300, channel 1 pins 304 corresponding to grid positions F2, F3, E3, D4, D7, E8, F8, and F9 are utilized to form input/output (I/O) channels (00, 01, 02, 03, 04, 05, 06, and 07) when coupled to their respective pins on the opposite NAND memory package across the PCB. Similarly, channel 0 pins 306 corresponding to grid positions M9, M8, N8, P7, P4, N3, M3, and M2 are utilized to form I/O channels (00, 01, 02, 03, 04, 05, 06, and 07) when coupled to their respective pins on the opposite NAND memory package across the PCB.

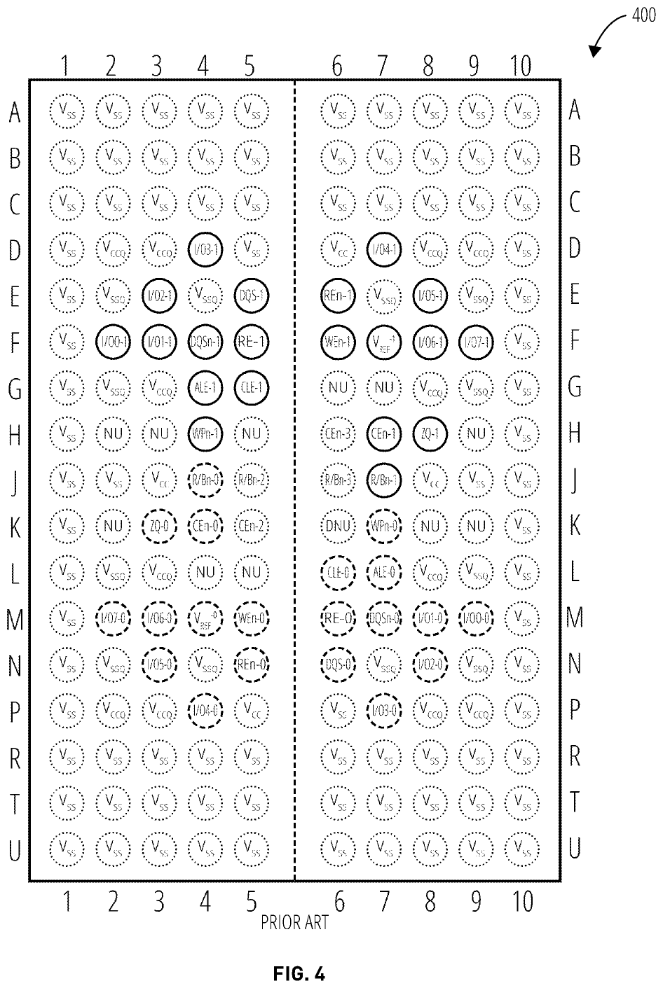

FIG. 4 illustrates a top view of a conventional pin assignments 400 illustrating the details of the individual pin assignments of a 170-pin BGA configuration. The meaning of the different pin labels is known in the art and need not be elaborated on.

FIG. 5 illustrates a cross sectional view of a memory device 500 in accordance with one embodiment. The memory device 500 includes a conventional pin assignment semiconductor package 508 with a plurality of pins 512, of which one row is depicted arranged left to right as A1, A2, A3, A4, A5, A6, A7, A8, A9, and A10. The conventional pin assignment semiconductor package 508 is mounted to the first side 516 of a PCB 502.

A reverse pin assignment semiconductor package 510 is mounted opposite the conventional pin assignment semiconductor package 508 on a second side 518 of the PCB 502. The reverse pin assignment semiconductor package 510 also comprises a plurality of pins 514, of which one row is also depicted arranged left to right A10, A9, A8, A7, A6, A5, A4, A3, A2, and A1. In the memory device 500 the conventional pin assignment semiconductor package 508 has the conventional pin assignments for a 170 pin JEDEC NAND package, while the reverse pin assignment semiconductor package 510 is internally configured to reverse the pin assignments such that pins having the same functional assignments are mirrored across the PCB 502. In other words, the reverse pin assignment semiconductor package 510 is internally configured in such a way that the pin functional alignment is a mirror image of the pin functional in the conventional pin assignment semiconductor package 508.

This arrangement enables corresponding channel pins to be positioned in direct functional alignment across the PCB 502 resulting in shorter stub lengths and simplified wire routing from the controller to the pins. For example pin A4 on the conventional pin assignment semiconductor package 508 mirrors pin A7 which is configured to function as a conventional pin A4 on the reverse pin assignment semiconductor package 510. Thus the memory channels served by pins A4 and A7 may utilize a more direct connection 504. Similarly, pin A6 on the conventional pin assignment semiconductor package 508 mirrors pin A5 which is configured to function as a conventional pin A6. The memory channels served by pins A5 and A6 may also utilize a more direct connection 506.

FIG. 6 illustrates a top view of a mirrored configuration routing 600 between pins of a conventional pin assignment NAND package and a mirrored pin assignment NAND package. The resulting mirrored pin-out alignment reduces stub length and simplifies routing from the controller 602 to the first side pin 604 (corresponding to first memory channel 610) and second side pin 606 (corresponding to second memory channel 612). The first memory channel 610 and the second memory channel 612 may each utilize only a single common via (via 608) to communicate with the controller 602, with no additional vias necessary in the routing from the controller 602 to the first side pin 604 and second side pin 606. Furthermore the routing between the controller 602 and first memory channel 610 and second memory channel 612 may be achieved in only two layers of the PCB, instead of requiring up to five layers as in the conventional approach.

FIG. 7 illustrates a top view of a mirrored configuration pinout 700 between a NAND memory package with a conventional pin assignment and a NAND memory package with a mirrored pin-out assignment. The mirrored configuration pinout 700 comprises inactive pins 702 (dotted outline), channel 1 pins 704 (solid outline), and channel 0 pins 706 (dashed outline). In the mirrored configuration pinout 700, channel 1 pins 704 corresponding to grid positions F9, F8, E8, D7, D4, E3, F3, and F2 correspond to I/O assignments 00, 01, 02, 03, 04, 05, 06, and 07 when coupled to pins on grid positions F2, F3, E3, D4, D7, E8, F8 and F9 on an opposite non-reversed packaged NAND across the PCB. Similarly, channel 0 pins 706 corresponding to grid positions M2, M3, N3, P4, P7, N8, M8, and M9 are utilized to form I/O assignments (00, 01, 02, 03, 04, 05, 06, and 07) when coupled to pins on grid positions M9, M8, N8, P7 P4, N3, M3 and M2 on the opposite non-reversed packaged NAND across the PCB.

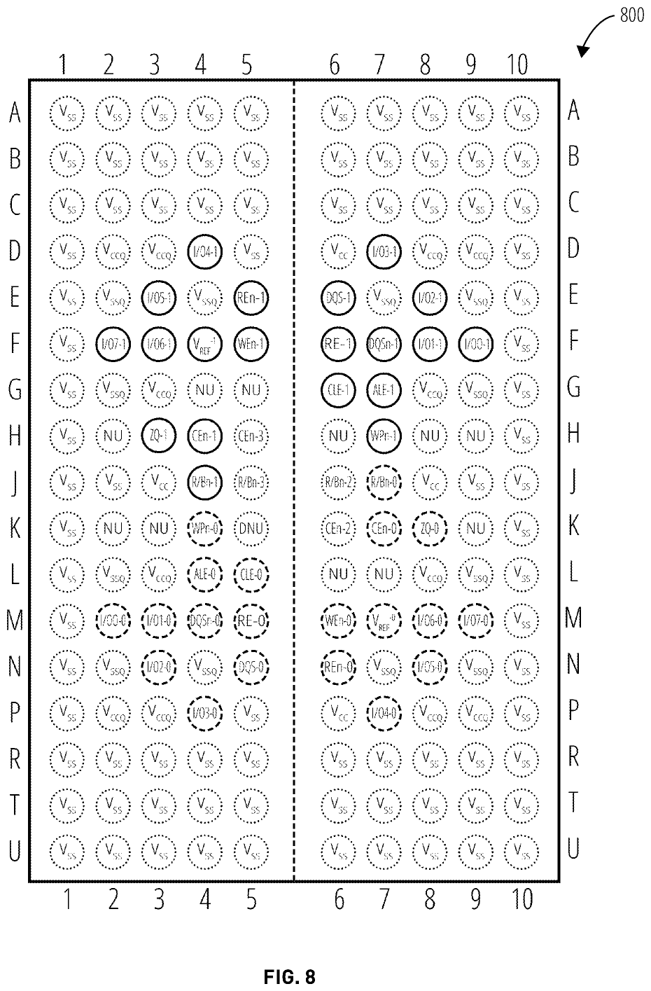

FIG. 8 illustrates a top view of a mirrored pin assignments 800 depicting individual pin assignments of a mirrored configuration of 170-pin BGA NAND memory packages. The meaning of the different pin labels are known in the art and need not be elaborated on here.

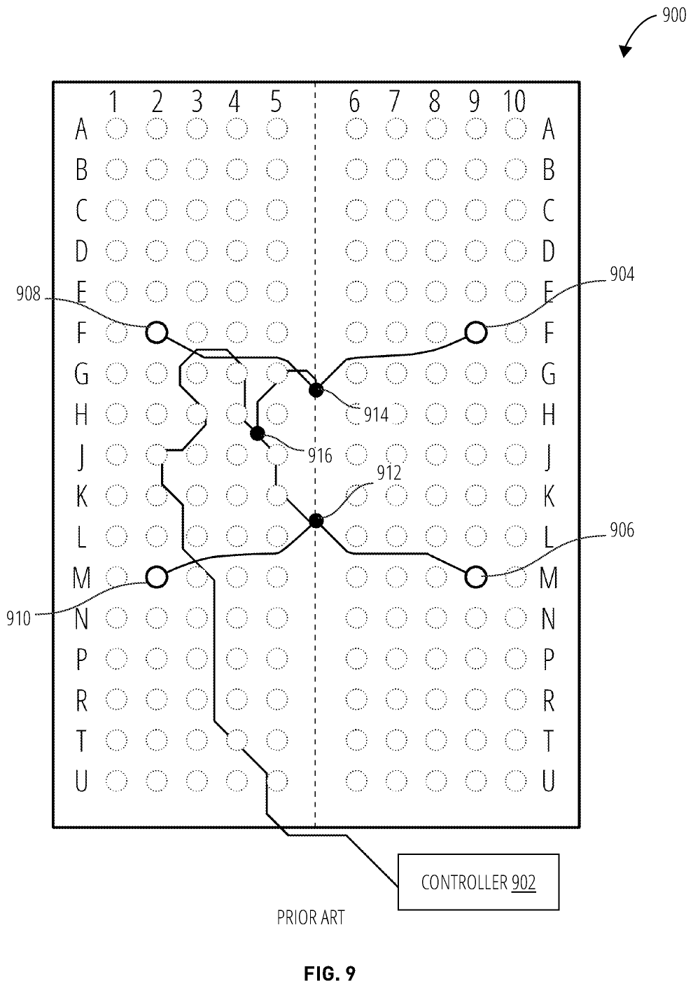

FIG. 9 illustrates a top view of a conventional configuration routing 900 from a controller 902 to a first side pin 908 (for a first memory channel) and to a second side pin 904 (for a second memory channel) at pin positions F2 and F9, respectively. Also depicted is the routing from the controller 902 to a first side pin 906 (for the first memory channel) and a second side pin 910 (for the second memory channel) at pin positions M2 and M9 respectively. At least two vias are needed for the routing to each pin. For routing to second side pin 904 and first side pin 908, via 914 and via 916 are needed. For routing to first side pin 906 and second side pin 910, via 916 and via 912 are needed. Additionally the routing for the pins traverses three or more layers of the PCB.

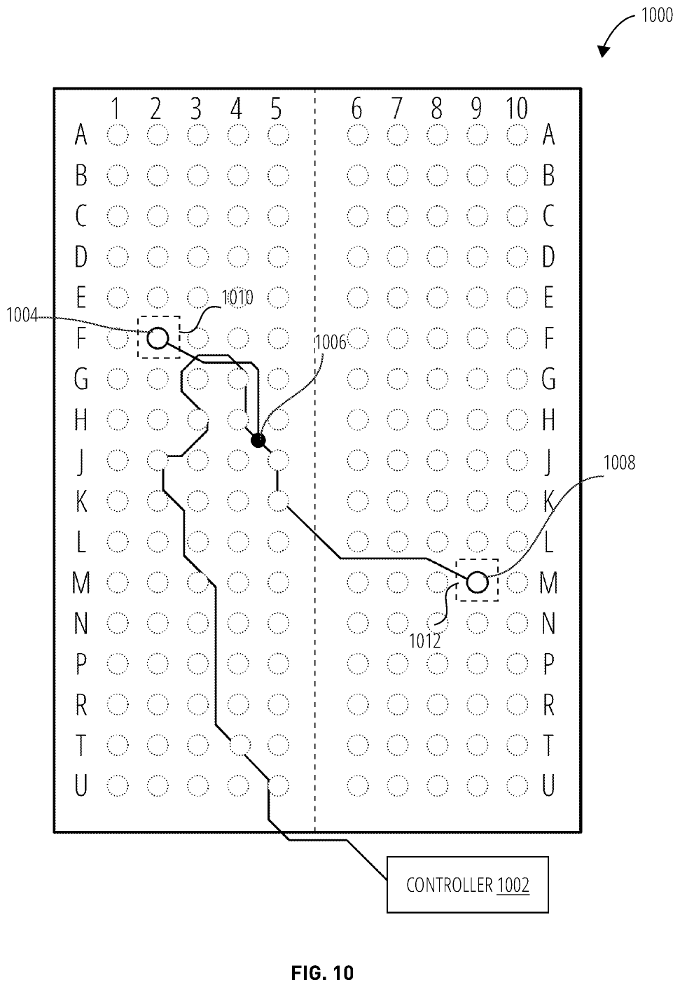

FIG. 10 illustrates a top view of a mirrored configuration routing 1000 with a mirrored pin-out alignment. In the mirrored configuration routing 1000 the pins assignments are in a mirrored alignment resulting in the first and second side pins 1004 corresponding to first memory channel 1010, and first and second side pins 1008 corresponding to second memory channel 1012, respectively being aligned to one another across the PCB. Due to the mirrored pin-out alignment, the connection lengths from the controller 1002 to the first memory channel 1010 and second memory channel 1012 are reduced compared to the connection lengths in the conventional configuration routing 900, and only require a single via 1006 to communicably couple to controller 1002. Furthermore, only two routing layers are needed in the PCB, as compared with up to five routing layers required in the conventional approach.

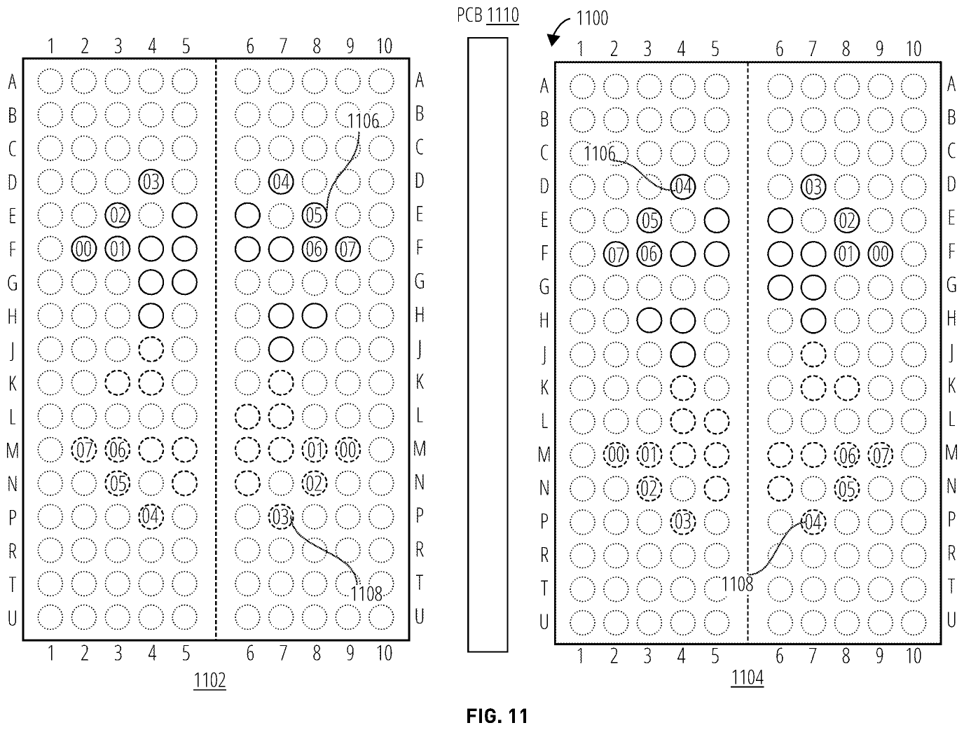

FIG. 11 depicts NAND memory package pair configuration 1100 between a conventional NAND package 1102 and a mirrored NAND package 1104 across a PCB 1110. In the NAND memory package pair configuration 1100, grid positions of F9, F8, E8, D7, D4, E3, F3, and F2 on the mirrored NAND package 1104 correspond to channel 1 pins 1106 with the I/O assignment of 00, 01, 02, 03, 04, 05, 06, and 07 and correspond to the grid positions F2, F3, E3, D4, D7, E8, F8, and F9 on the conventional NAND package 1102 with the same I/O assignments. Similarly, grid positions M2, M3, N3, P4, P7, N8, M8, and M9 on the mirrored NAND package 1104 correspond to channel 0 pins 1108 with the I/O assignments 00, 01, 02, 03, 04, 05, 06, and 07 and correspond to grid positions M9, M8, N8, P7, P4, N3, M3 and M2, on the conventional NAND package 1102 with the same I/O assignments.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

What is claimed is:

1. An apparatus comprising:
a printed circuit board;
a first semiconductor package comprising a plurality of pins mounted on a first side of the printed circuit board; and
a second semiconductor package mounted on a second side of the printed circuit board opposite the first side, the second semiconductor package comprising a mirrored pin assignment of the first semiconductor package.

2. The apparatus of claim 1, the first semiconductor package and the second semiconductor package each comprising a NAND memory package.

3. The apparatus of claim 2, the NAND memory package comprising 170 pins.

4. The apparatus of claim 1, the printed circuit board utilizing signal routing to the first semiconductor package and the second semiconductor package in only two layers.

5. The apparatus of claim 1, further comprising:
a controller; and
routing from the controller to each pair of corresponding pin assignments on the first semiconductor package and the second semiconductor package utilizing a single via.

6. The apparatus of claim 5, further comprising:
the routing from the controller to the first semiconductor package and the second semiconductor package utilizing only two layers in the printed circuit board.

7. The apparatus of claim 1, further comprising:
a controller; and
wherein a stub length for routing between the controller and the first semiconductor package, and the controller and the second semiconductor package, is limited to a via length of the printed circuit board.

8. A memory device comprising:
at least two NAND memory packages mounted pairwise opposite one another on a printed circuit board; and
one of the NAND memory packages of each pair comprising a mirrored pin assignment of the other of the NAND memory packages of the pair.

9. The apparatus of claim 8, each of the NAND memory packages comprising a memory channel.

10. The apparatus of claim 8, each of the NAND memory packages a JEDEC 170 pin package.

11. The apparatus of claim 8, the printed circuit board utilizing signal routing in only two layers to each of the NAND memory packages.

12. The apparatus of claim 8, further comprising:
a controller; and
routing from the controller to each of the NAND memory packages utilizing only a single via per pin of the NAND memory packages.

13. The apparatus of claim 12, further comprising:
the routing from the controller to each of the NAND memory packages utilizing only two layers in the printed circuit board.

14. The apparatus of claim 8, further comprising:
a controller; and
wherein a stub length for routing between the controller and the NAND memory packages is limited to a via length of the printed circuit board.

15. An apparatus comprising:
control means; and
means for mounting a first semiconductor package and a second semiconductor package, each comprising at least 170 pins, opposite one another on a printed circuit board, such that routing from the control means to each semiconductor package utilizes a single via per pin and only two routing layers in the printed circuit board.
